(19) United States
(12) Patent Application Publication
(10) Pub. No.: US 2026/0206418 A1
(43) Pub. Date: Jul. 16, 2026

(54) ELECTRONIC DEVICE

(71) Applicant: Innolux Corporation, Miaoli County (TW)

(72) Inventors: Chandra Lius, Miaoli County (TW); Kuan-Feng Lee, Miaoli County (TW)

(73) Assignee: Innolux Corporation, Miaoli County (TW)

(21) Appl. No.: 19/412,868

(22) Filed: Dec. 9, 2025

(30) Foreign Application Priority Data
Jan. 10, 2025 (CN) 202510044085.1

(51) Int. Cl. H10K 59/121; H10H 29/32; H10H 29/49; H10K 39/32; H10K 59/131

(52) U.S. Cl. CPC H10K 59/1213; H10H 29/32; H10H 29/49; H10K 39/32; H10K 59/131

(57) ABSTRACT

An electronic device includes a substrate, a first signal line disposed on the substrate, first and second electronic units, first and second transistors, and a first connecting element. The first and second electronic units are disposed on the substrate and electrically connected to the first signal line. The first transistor is disposed on the substrate and has a first control element, a first conductive element, and a first semiconductor. The second transistor is disposed on the substrate and has a second control element, a second conductive element, and a second semiconductor. The first connecting element is electrically connected to the first control element and the second control element. The first semiconductor overlaps with the first control element and is disposed between the substrate and the first control element. The second semiconductor overlaps with the second control element and is disposed between the substrate and the second control element.

### CROSS-REFERENCE TO RELATED APPLICATION

This application claims the priority benefit of China application serial no. 202510044085.1, filed on January 10, 2025. The entirety of the above-mentioned patent application is hereby incorporated by reference herein and made a part of this specification.

### BACKGROUND

### Technical Field

The disclosure relates to an electronic device.

### Related Art

As the technology related to electronic devices continues to advance, electronic devices are developing to provide favorable quality of use. However, electronic devices that have both high resolution and high refresh rate are not yet available.

### SUMMARY

Some embodiments of the disclosure are directed to an electronic device with improved quality of use.

According to some embodiments of the disclosure, an electronic device is provided, which includes a substrate, a first signal line, a first electronic unit, a second electronic unit, a first transistor, a second transistor, and a first connecting element. The first signal line is disposed on the substrate. The first electronic unit and the second electronic unit are disposed on the substrate and are respectively electrically connected to the first signal line. The first transistor is disposed on the substrate and has a first control element, a first conductive element, and a first semiconductor. The first conductive element is electrically connected to the first semiconductor, and the first control element is electrically connected to the first electronic unit. The second transistor is disposed on the substrate and has a second control element, a second conductive element, and a second semiconductor. The second conductive element is electrically connected to the second semiconductor, and the second control element is electrically connected to the second electronic unit. The first connecting element is electrically connected to the first control element of the first transistor and the second control element of the second transistor. The first semiconductor overlaps with the first control element and is disposed between the substrate and the first control element. The second semiconductor overlaps with the second control element and is disposed between the substrate and the second control element.

### BRIEF DESCRIPTION OF THE DRAWINGS

FIG. 1A is a local equivalent circuit diagram of an electronic device according to the first embodiment, FIG. 1B is a local top view of the electronic device in FIG. 1A, and FIG. 1C is a local cross-sectional view of the electronic device in FIG. 1A.

FIG. 2A is a circuit diagram of an electronic device according to the second embodiment, FIG. 2B is a local top view of the electronic device in FIG. 2A, and FIG. 2C is a local cross-sectional view of the electronic device in FIG. 2A.

FIG. 3A is a local cross-sectional view of an electronic device according to the third embodiment, FIG. 3B is a local cross-sectional view of an electronic device according to the fourth embodiment, and FIG. 3C is a local top view of the electronic device according to the fourth embodiment.

FIG. 4A is a circuit diagram of an electronic device according to the fifth embodiment, and FIG. 4B is a drive timing diagram of the electronic device in FIG. 4A.

FIG. 5 is a local cross-sectional view of an electronic device according to the sixth embodiment.

FIG. 6 is a local cross-sectional view of an electronic device according to the seventh embodiment.

FIG. 7A is a local cross-sectional view of an electronic device according to the eighth embodiment, and FIG. 7B to FIG. 7I are a local top view of the electronic device in FIG. 7A.

FIG. 8A is a local cross-sectional view of an electronic device according to the tenth embodiment, and FIG. 8B is a local top view of the electronic device in FIG. 8A.

FIG. 9A is a local cross-sectional view of an electronic device according to the eleventh embodiment, and FIG. 9B is a local top view of the electronic device in FIG. 9A.

FIG. 10 is a local cross-sectional view of an electronic device according to the twelfth embodiment.

FIG. 11 is a local cross-sectional view of an electronic device according to the thirteenth embodiment.

FIG. 12 is a local cross-sectional view of an electronic device according to the fourteenth embodiment.

FIG. 13A is a top view of an electronic device according to the fourteenth embodiment, and FIG. 13B is a circuit diagram of the electronic device according to the fourteenth embodiment.

FIG. 14A is a circuit diagram of an electronic device according to the fifteenth embodiment, and FIG. 14B is a circuit diagram of an electronic device according to the sixteenth embodiment.

### DESCRIPTION OF THE EMBODIMENTS

Reference will now be made in detail to exemplary embodiments, examples of which are illustrated in the accompanying drawings. Wherever possible, the same reference numerals are used in the drawings and the description to refer to the same or similar parts.

The disclosure can be understood by referring to the following detailed description in combination with the accompanying drawings. It should be noted that the multiple drawings in this disclosure only depict a part of the electronic device, and specific components in the drawings may not be drawn according to actual scale. The number and size of each component in the drawings are only for exemplary purpose, and are not intended to limit the scope of the disclosure.

Throughout the specification and the appended claims, certain terms are used to refer to specific components. Those skilled in the art should understand that electronic device manufacturers may refer to the same components by different names. The disclosure does not intend to distinguish those components with the same function but different names. In the following description and claims, the terms "including," "containing," and "having" are open-ended terms, so they should be interpreted as "including but not limited to...".

Directional terms mentioned in this specification, such as "up," "down," "front," "back," "left," and "right," merely refer to directions in the accompanying drawings. Therefore, the directional terms used is for illustration, not for limiting this disclosure. In the drawings, each drawing shows the general features of the method, structure, and/or material used in a specific embodiment. However, these drawings should not be construed as defining or limiting the scope or nature of the embodiments.

When a corresponding member (such as a layer or a region) is described as being "on another member," it may be directly on another member, or there may be other members therebetween. On the other hand, when a member is described as being "directly on another member," no member exists therebetween, unless otherwise specified in the specification. In addition, when a member is described as being "on another member," the two members have a vertical relationship in the top view direction and this member may be located above or below another member, and the vertical relationship depends on the device orientation.

Terms such as "equal" or "same," and "substantially" or "approximately" are generally interpreted as being within 20% of a given value or range, or interpreted as being within 10%, 5%, 3%, 2%, 1%, or 0.5% of the given value or range.

Ordinal numbers in the specification and claims, such as "first" and "second," are used to modify a component, and do not imply or represent that the (or these) component(s) has (or have) any ordinal number and do not indicate any order between a component and another component, or an order in a manufacturing method. These ordinal numbers are merely used to clearly distinguish a component having a name with another component having the same name. Different terms may be used in the claims and the specification.

In the following embodiments, features from several different embodiments may be substituted, recombined, or mixed to complete other embodiments without departing from the spirit of the disclosure. Electrical connection or coupling described in the disclosure may refer to direct connection or indirect connection.

In the disclosure, a thickness, a length, a width, and an area may be measured using an optical microscope, and the thickness may be measured using a cross-sectional image in an electronic microscope. In addition, any two values or directions used for comparison may have certain errors. If a first value is equal to a second value, it implies that there may be an error of about 10% between the first value and the second value; if a first direction is perpendicular to a second direction, an angle between the first direction and the second direction may be between 80degrees and 100 degrees; and if the first direction is parallel to the second direction, the angle between the first direction and the second direction may be between 0 degrees and 10 degrees.

The electronic device may include a display device, a backlight device, an antenna device, a sensing device, or a splicing device. The electronic device may be a foldable or flexible electronic device. The display device may be a non-self-luminous display device or a self-luminous display device. The antenna device may be a liquid crystal type antenna device or a non-liquid crystal type antenna device. The sensing device may be a device for sensing electromagnetic waves, capacitance, light, thermal energy, or ultrasonic waves, but is not limited thereto. The electronic device may include an electronic unit, and the electronic unit may include a passive element and an active element. The following will elaborate the content of the disclosure based on an electronic device, but the disclosure is not limited thereto.

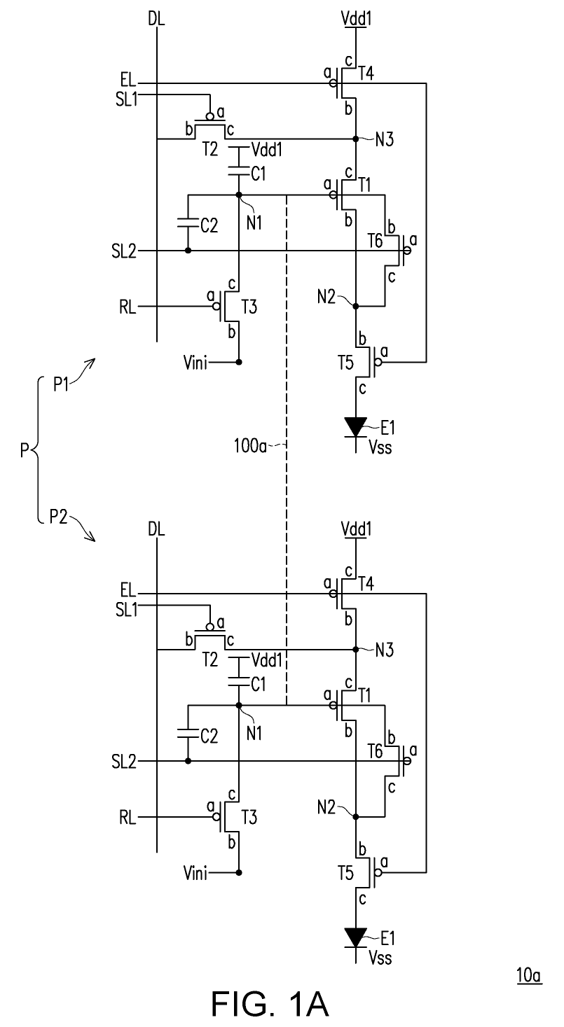

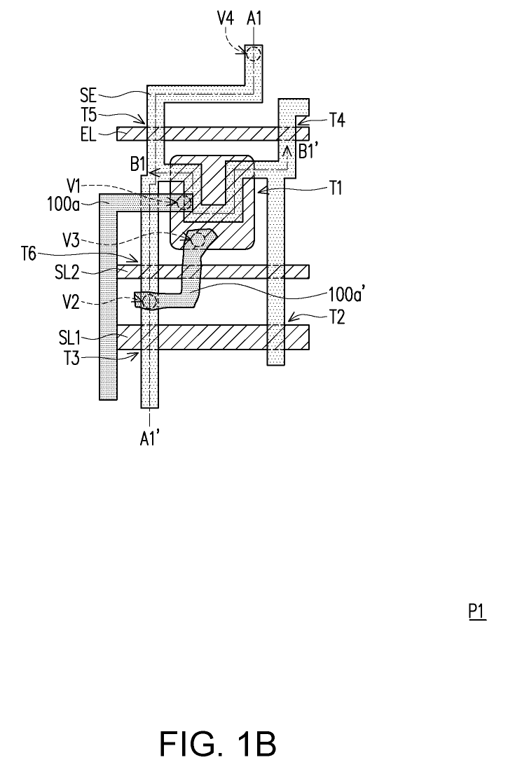

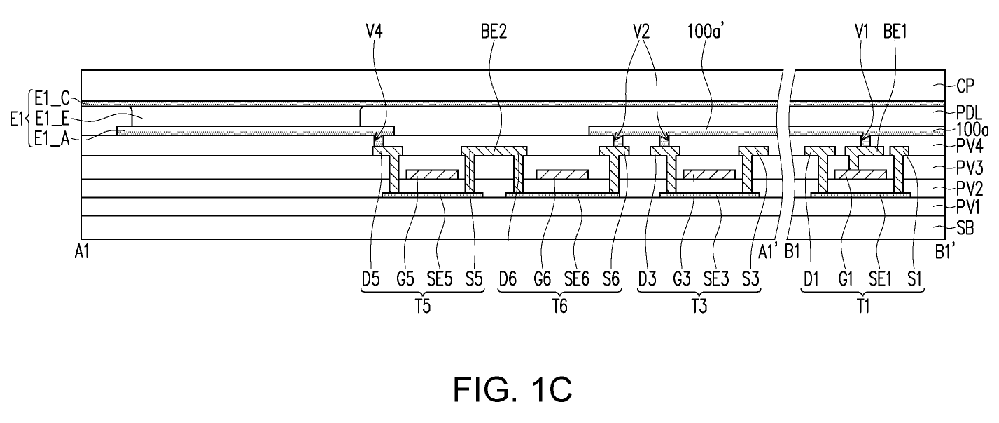

Referring to FIG. 1A, an electronic device 10a includes a pixel unit P. In this embodiment, the electronic device 10a is an organic light-emitting diode (OLED) display device.

Further referring to FIG. 1A to FIG. 1C, the pixel unit P includes a sub-pixel unit P1 and a sub-pixel unit P2, and either of the sub-pixel units P1 and P2 includes an electronic unit E1, multiple transistors and at least one capacitor. Specifically, the sub-pixel unit P1 includes an electronic unit E1, a drive transistor T1, a switching transistor T2, a reset transistor T3, a light-emitting transistor T4, a light-emitting transistor T5, a switching transistor T6, capacitors C1 and C2.

The electronic unit E1 may be an organic light-emitting diode. An anode terminal of the electronic unit E1 is electrically connected to a second terminal c of the light-emitting transistor T5, and a cathode terminal of the electronic unit E1 is electrically connected to a reference voltage line Vss. A control terminal a of the drive transistor T1 is electrically connected to a node N1, a first terminal b of the drive transistor T1 is electrically connected to a node N2, and a second terminal c of the drive transistor T1 is electrically connected to a node N3. A control terminal a of the switching transistor T2 is electrically connected to a scan line SL1, a first terminal b of the switching transistor T2 is electrically connected to a data line DL, and a second terminal c of the switching transistor T2 is electrically connected to the node N3. A control terminal a of the reset transistor T3 is electrically connected to a reset line RL, a first terminal b of the reset transistor T3 is electrically connected to an initialization voltage line Vini, and a second terminal c of the reset transistor T3 is electrically connected to the node N1. A control terminal a of the light-emitting transistor T4 is electrically connected to an emission control line EL, a first terminal b of the light-emitting transistor T4 is electrically connected to the node N3, and a second terminal c of the light-emitting transistor T4 is electrically connected to a power voltage line Vdd1. A control terminal a of the light-emitting transistor T5 is electrically connected to the emission control line EL, a first terminal b of the light-emitting transistor T5 is electrically connected to the node N2. A control terminal a of the switching transistor T6 is electrically connected to a scan line SL2, a first terminal b of the switching transistor T6 is electrically connected to the node N1, and a second terminal c of the switching transistor T6 is electrically connected to the node N2. A first terminal of the capacitor C1 is electrically connected to the power voltage line Vdd1, and a second terminal of the capacitor C1 is electrically connected to the node N1. A first terminal of the capacitor C2 is electrically connected to the node N1, and a second terminal of the capacitor C1 is electrically connected to the scan line SL2.

The sub-pixel unit P1 and the sub-pixel unit P2 are electrically connected to each other through a connecting element 100a. The electronic device 10a may include the following layers.

An insulation layer PV1 is disposed on a substrate SB. A semiconductor SE is disposed on the insulation layer PV1. The semiconductor SE includes the respective semiconductors (the semiconductor SE1, semiconductor SE3, semiconductor SE5, and semiconductor SE6) of the respective transistors. An insulation layer PV2 is disposed on the insulation layer PV1. A first conductive layer is disposed on the insulation layer PV2. The first conductive layer is used to form control elements to serve as the respective gates of the drive transistor T1, the switching transistor T2, the reset transistor T3, the light-emitting transistor T4, the light-emitting transistor T5, and the switching transistor T6 as control terminals. The first conductive layer is also used to form the scan line SL1, the scan line SL2, the emission control line EL, and the reset line RL. An insulation layer PV3 is disposed on the insulation layer PV2. A second conductive layer is disposed on the insulation layer PV3. The second conductive layer is used to form conductive elements to serve as the respective sources and drains (the source S1 and drain D1, source S3 and drain D3, source S5 and drain D5, and source S6 and drain D6) of the respective transistors. The second conductive layer is also used to form the data line DL, the initialization voltage line Vini, the power voltage line Vdd1, and the reference voltage line Vss. The second conductive layer also includes a bridge electrode BE1 electrically connected to the gate G1 of the drive transistor T1, and includes a bridge electrode BE2 electrically connected to the source D5 and the drain D6.

The respective gates of the drive transistor T1, the switching transistor T2, the reset transistor T3, the light-emitting transistor T4, the light-emitting transistor T5, and the switching transistor T6 are disposed between the connecting element 100a and the respective semiconductors of the respective transistors. Thus, the respective transistors all have top-gate structures. The respective sources and drains of the respective transistors are in direct contact with the respective semiconductors thereof. An insulation layer PV4 is disposed on the insulation layer PV3. A third conductive layer is disposed on the insulation layer PV4. The third conductive layer is used to form a first electrode E1_A of the electronic unit E1 and the connecting element 100a. The first electrode E1_A of the electronic unit E1 is electrically connected to the drain D5 of the light-emitting transistor T5 through a via V4 of the insulation layer PV4, and the connecting element 100a is electrically connected to the gate G1 of the drive transistor T1 through a via V1 of the insulation layer PV4 and the bridge electrode BE1. The third conductive layer also includes a connecting element 100a' and a bridge electrode BE2, wherein the connecting element 100a' is electrically connected to the source S6, the drain D3, and the gate G1 through a via V2 and a via V3. The drain D6 is electrically connected to the source S5 through the bridge electrode BE2.

Based on this, by disposing the connecting element 100a, the drive transistor T1 in the sub-pixel unit P1 may be electrically connected to the drive transistor T1 in the sub-pixel unit P2.

A pixel definition layer PDL is disposed on the insulation layer PV4. The electronic unit E1 includes a first electrode E1_A, the light-emitting layer E1_E, and a second electrode E1_C. The light-emitting layer E1_E is disposed on the first electrode E1_A. The second electrode E1_C is disposed on the light-emitting layer E1_E, and is also disposed on the pixel definition layer PDL. A covering layer CP is disposed on the second electrode E1_C.

In this embodiment, during a stage when the electronic unit E1 is driven to emit light, the scan line SL1, the scan line SL2, and the reset line RL are used to turn off the switching transistor T2, the switching transistor T6, and the reset transistor T3, and the emission control line EL is used to turn on the light-emitting transistor T4 and the light-emitting transistor T5. The voltage stored in the capacitors C1 and C2 controls the drive transistor T1 to turn on, so that the drain of the drive transistor T1 may receive voltage from the power voltage line Vdd1 through the light-emitting transistor T4, causing the electronic unit E1 to emit electromagnetic waves.

Based on the above, by disposing the connecting element 100a, the electronic unit E1 in the sub-pixel unit P1 may be driven again to emit light in the stage when the electronic unit E1 in the sub-pixel unit P2 is driven to emit light, thereby improving the brightness of light emission and/or display quality of the electronic unit E1 in the sub-pixel unit P1.

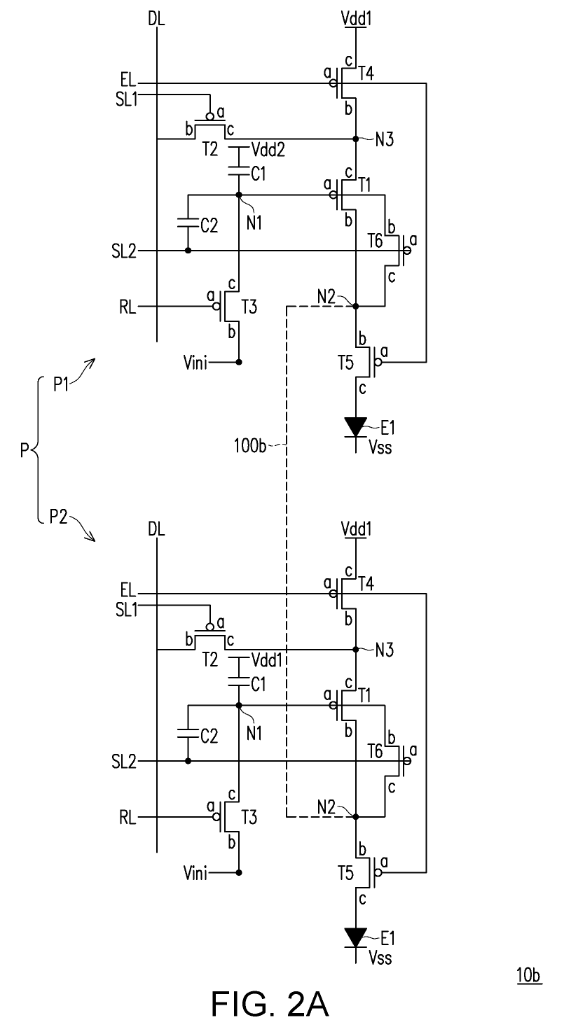

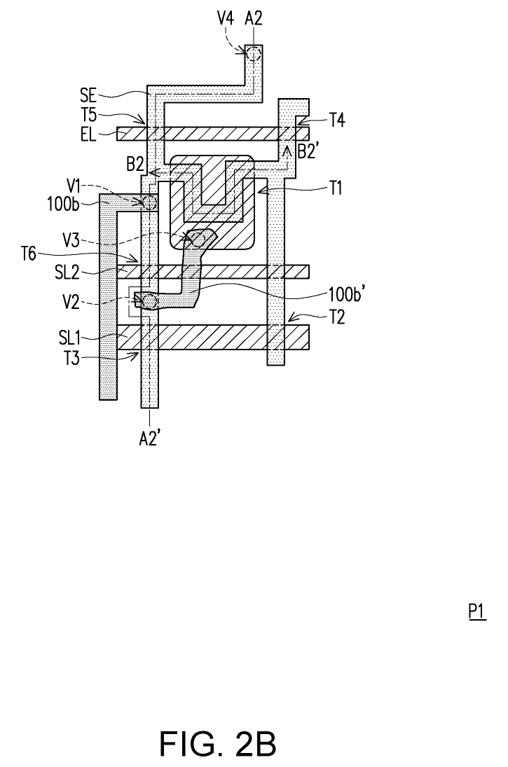

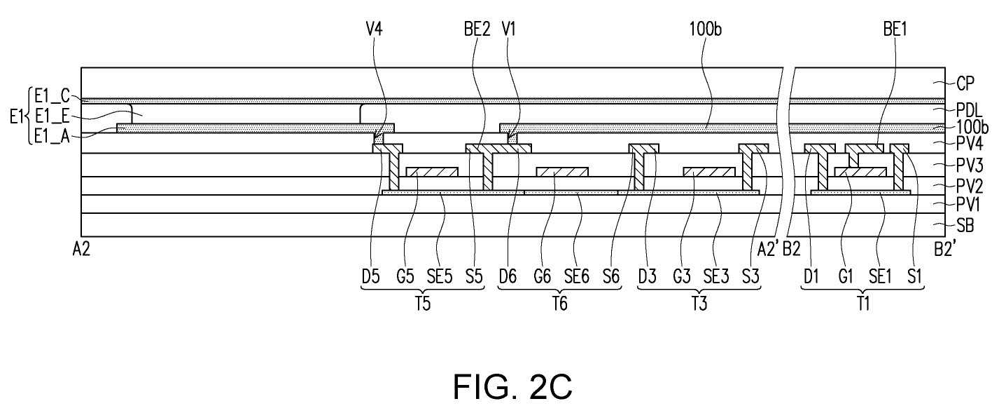

Referring to FIG. 2A to FIG. 2C, the main difference between an electronic device 10b and the electronic device 10a is that a connecting element 100b is electrically connected to the source S5 of the light-emitting transistor T5 through the via V1. Based on this, the light-emitting transistors T5 in the sub-pixel units P1 and P2 may be electrically connected to each other.

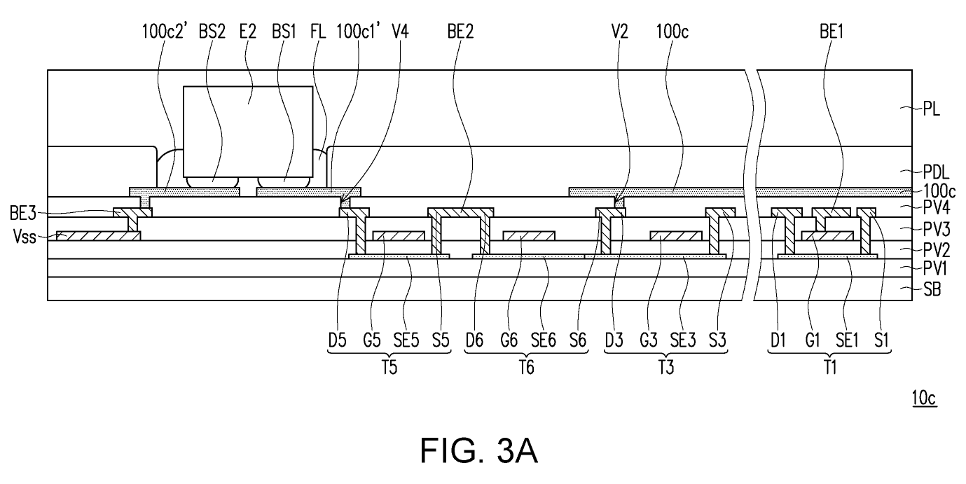

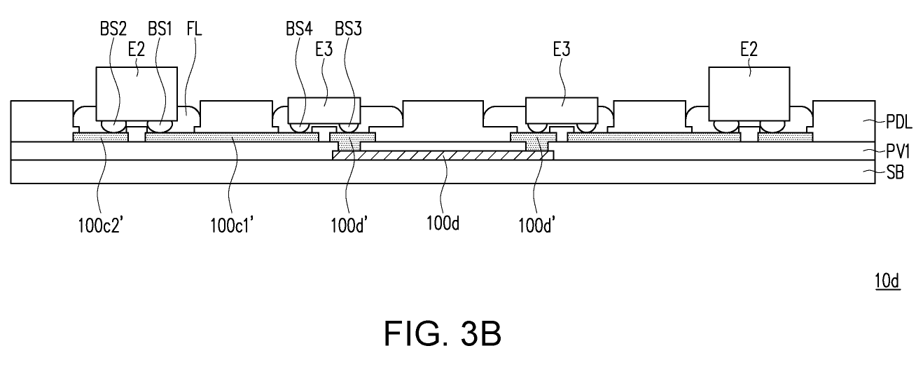

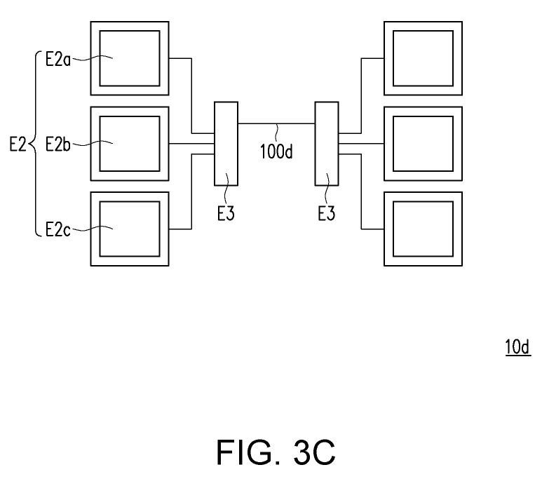

Referring to FIG. 3A, the main difference between an electronic device 10c and the electronic device 10a is that the electronic unit E2 is a micro light-emitting diode (Micro LED). The first electrode (not shown) in the electronic unit E2 is electrically connected to the drain D5 of the light-emitting transistor T5 through a bonding structure BS1 and a connecting element 100c1' in the third conductive layer, and the second electrode (not shown) in the electronic unit E2 is electrically connected to the reference electrode line Vss through a bonding structure BS2, a connecting element 100c2' in the third conductive layer, and a bridge electrode BE3. The position of the electronic unit E2 is defined by the pixel definition layer PDL. A filling layer FL is disposed in an opening defined by the pixel definition layer PDL, and is disposed adjacent to or around the electronic unit E2. A packaging layer PL is disposed on the electronic unit E2.

Referring to FIG. 3B and FIG. 3C, the main difference between an electronic device 10d and the electronic device 10c is that the electronic device 10d also includes a micro integrated circuit (Micro IC). More specifically, the electronic unit E2 is a Micro LED, and an electronic unit E3 is a Micro IC, wherein the electronic unit E2 includes an electronic unit E2a emitting red light, an electronic unit E2b emitting green light, and an electronic unit E2c emitting blue light. The first electrode (not shown) in the electronic unit E2 is electrically connected to the connecting element 100c1' in the third conductive layer through the bonding structure BS1, and the electronic unit E3 is electrically connected to the connecting element 100c1' through a bonding structure BS4. Based on this, the electronic unit E2 may be driven by the electronic unit E3. The electronic unit E3 is electrically connected to a connecting element 100d' in the third conductive layer through a bonding structure BS3, wherein the connecting element 100d' belongs to the same layer as the connecting element 100c1' and the connecting element 100c2'. In this embodiment, the electronic device 10d also includes a connecting element 100d, wherein the connecting element 100d is electrically connected to the adjacent connecting elements 100d'. The connecting element 100d may be part of the first conductive layer. For instance, the connecting element 100d belongs to the same layer as the respective gates of the respective transistors. Based on this, the adjacent electronic units E3 is electrically connected to each other. When one electronic unit E2 is driven by one electronic unit E3, the adjacent electronic unit E2 is also driven by the same electronic unit E3, thereby improving the brightness of light emission and/or display or light-emitting quality of the electronic unit E2.

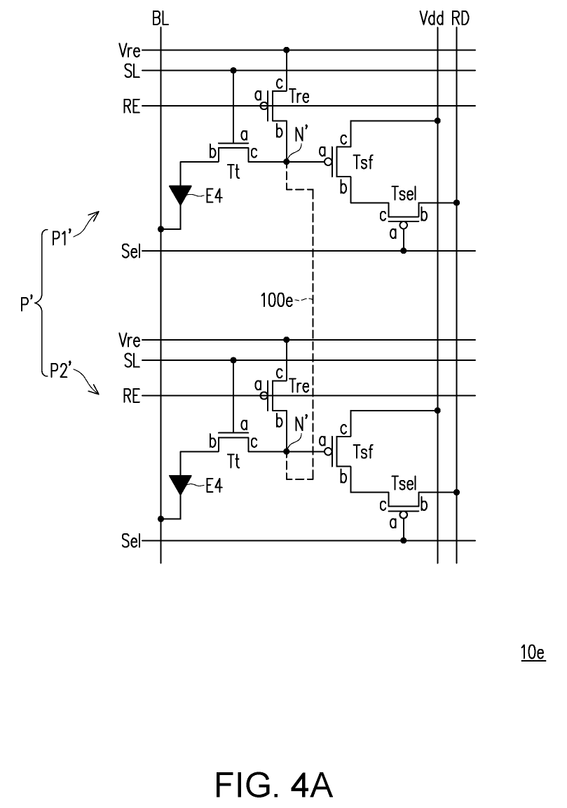

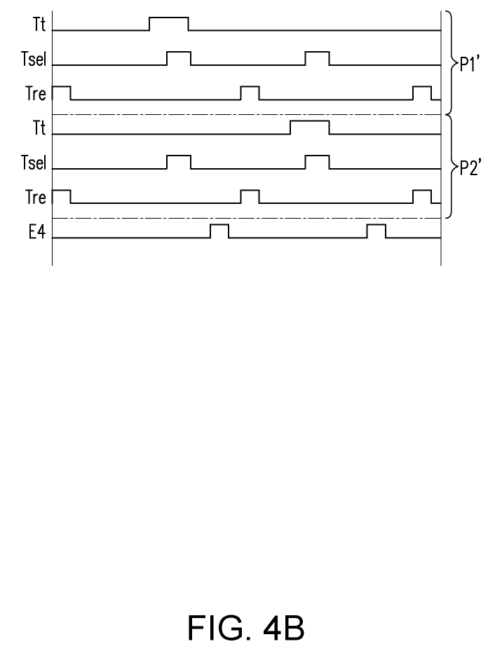

Referring to FIG. 4A, the main difference between an electronic device 10e and the electronic device 10a is that an electronic unit E4 in the electronic device 10e is a sensing unit. In this embodiment, a pixel unit P' may include a sub-pixel unit P1' and a sub-pixel unit P2', and either of the sub-pixel units P1' and P2' includes an electronic unit E4 and multiple transistors. Specifically, the sub-pixel unit P1' includes the electronic unit E4, a selection transistor Tsel, a drive transistor Tsf, a reset transistor Tre, and a transfer transistor Tt. The electronic unit E4 is a light sensing unit configured to sense electromagnetic waves. A photosensitive layer (not shown) in the electronic unit E4 converts received photons into carriers, and the carriers are read by a read line RD electrically connected thereto, thereby implementing the function of light detection.

Referring to FIG. 4B, the electronic device 10e is operated through the following steps.

Step (1): Perform a reset step. A signal is provided to the control terminal a of the reset transistor Tre using the reset line RE to turn on the reset transistor Tre, so that the voltage at the node N' is reset or modulated to the reset voltage.

Step (2): Perform a light exposure step. The reset transistor Tre is turned off and the electronic unit E4 is exposed to light for a specific time. Since the electronic unit E4 may receive light and generate a signal, the voltage at the node N' changes, wherein the voltage at the node N' may be affected by the intensity and/or duration of the light illuminating the electronic unit E4.

Step (3): Perform a read step. After the electronic unit E4 has been exposed to light for a specific time, a signal is provided to the control terminal a of the selection transistor Tsel using the selection line Sel to turn on the selection transistor Tsel. Therefore, the drive transistor Tsf, which has a power supply voltage applied to the second terminal c, outputs a current at the first terminal b, and this current may be provided to the read line RD through the turned-on selection transistor Tsel. It should be noted that the magnitude of the current output by the drive transistor Tsf may be affected by the voltage at the node N', that is, affected by the intensity and/or duration of the light illuminating the electronic unit E4. Subsequently, a processing unit or circuit (not shown) electrically connected to the read line RD may convert the sensed current into a sensed voltage and determine the intensity of the light received by the electronic device 10e.

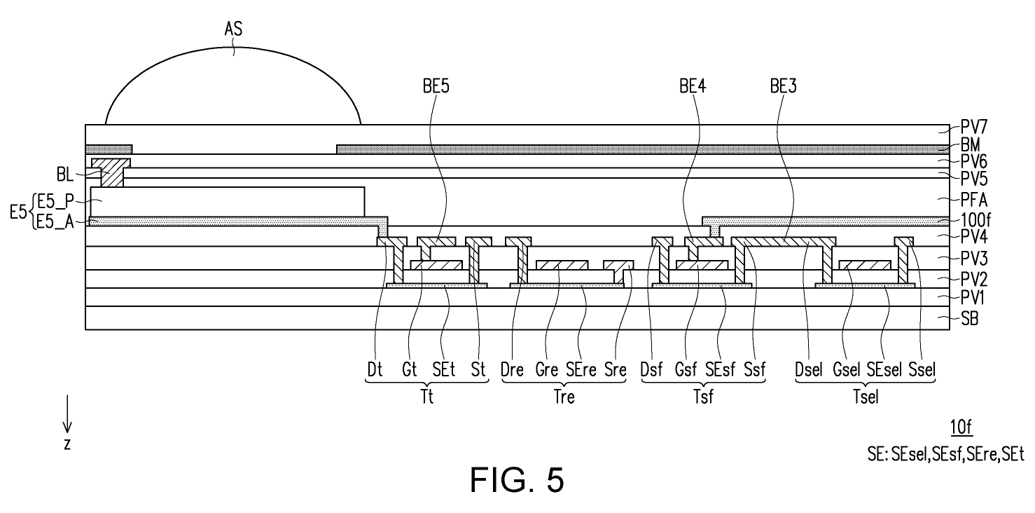

Referring to FIG. 5, the main difference between an electronic device 10f and the electronic device 10a is an electronic unit E5 in the electronic device 10f is a sensing unit. The electronic unit E5 may be an organic optical detector (OPD) or a PIN diode-based photodetector.

More specifically, the electronic device 10f also includes a planarization layer PFA, an insulation layer PV5, a signal line BL, an insulation layer PV6, and a shielding pattern BM.

The planarization layer PFA is disposed on the electronic unit E5. The insulation layer PV5 is disposed on the planarization layer PFA. The signal line BL is disposed on the insulation layer PV5, and is electrically connected to the electronic unit E5. The insulation layer PV6 is disposed on the insulation layer PV5, and covers the signal line BL. The shielding pattern BM is disposed on the insulation layer PV6. In this embodiment, the shielding pattern BM may be disposed to correspond to at least the selection transistor Tsel, the drive transistor Tsf, the reset transistor Tre, and the transfer transistor Tt. An insulation layer PV7 is disposed on the insulation layer PV6. An adjustment structure AS is disposed on the insulation layer PV7. In this embodiment, the adjustment structure AS at least partially overlaps with the electronic unit E5 in the top view direction z of the electronic device 10f. In some embodiments, the adjustment structure AS may be a biconvex lens, a plano-convex lens, or a convex-concave lens. By disposing the adjustment structure AS, the electronic unit E5 may receive a relatively collimated light signal through the adjustment structure AS, which can effectively suppress the crosstalk phenomenon of signals from non-corresponding areas or background noise, to further increase the signal-to-noise ratio (SNR) of the signal and improve the sensing effect.

The semiconductor SE includes the respective semiconductors (the semiconductor SEsel, semiconductor SEsf, semiconductor SEre, and semiconductor SEt) of the selection transistor Tsel, the drive transistor Tsf, the reset transistor Tre, and the transfer transistor Tt. The first conductive layer includes the respective gates (the gate Gsel, gate Gsf, gate Gre, and gate Gt) of the respective transistors. The second conductive layer includes the respective sources and drains (the source Ssel and drain Dsel, source Ssf and drain Dsf, source Sre and drain Dre, and source St and drain Dt) of the selection transistor Tsel, the drive transistor Tsf, the reset transistor Tre, and the transfer transistor Tt, the power voltage line Vdd, and the read line RD. Additionally, the second conductive layer also includes the bridge electrode BE3, the bridge electrode BE4, and the bridge electrode BE5. The bridge electrode BE3 is electrically connected to the drain Dsel of the selection transistor Tsel and the source Ssf of the drive transistor Tsf. The bridge electrode BE4 is directly connected to the gate Gsf of the drive transistor Tsf and the connecting element 100f, thereby being electrically connected to each other. Specifically, the connecting element 100f, the drive transistor Tsf, the reset transistor Tre, and the transfer transistor Tt may be electrically connected to one another at a node (the node N' shown in FIG. 4A). The bridge electrode BE5 is electrically connected to the first electrode E5_A of the electronic unit E5 and the drain Dt of the transfer transistor T.

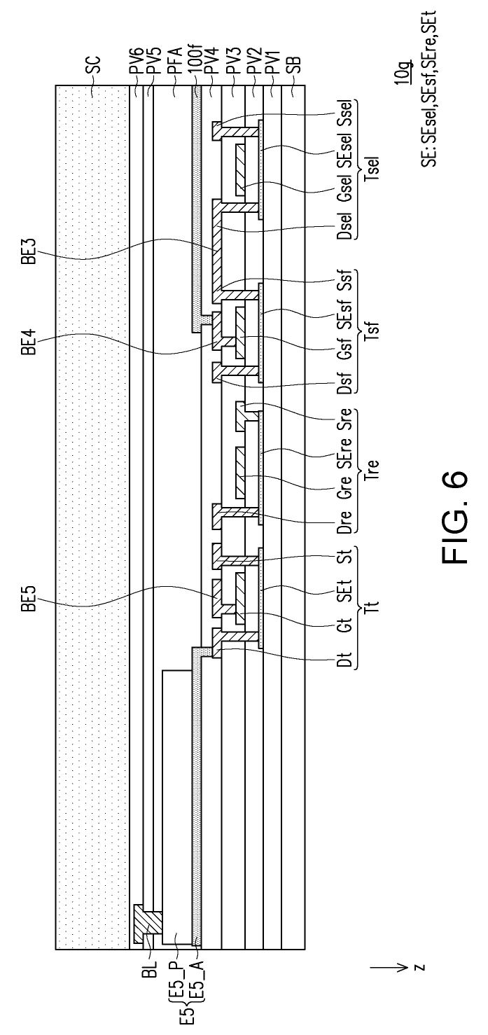

Referring to FIG. 6, the main difference between an electronic device 10g and the electronic device 10f is that the electronic unit E5 is an X-ray sensing unit. The electronic device 10g may includes a scintillator SC disposed on the insulation layer PV6. The material of the scintillator SC includes suitable materials. Additionally, the connecting element 100f overlaps with the scintillator SC.

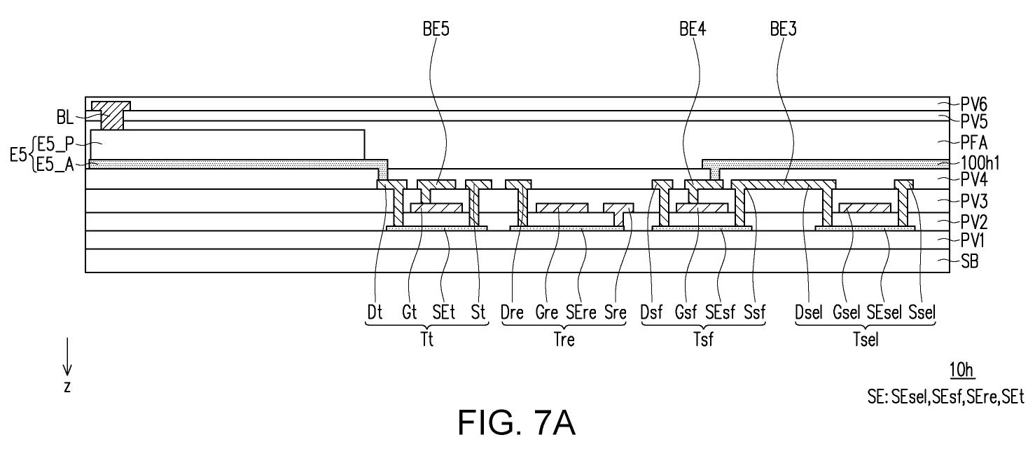

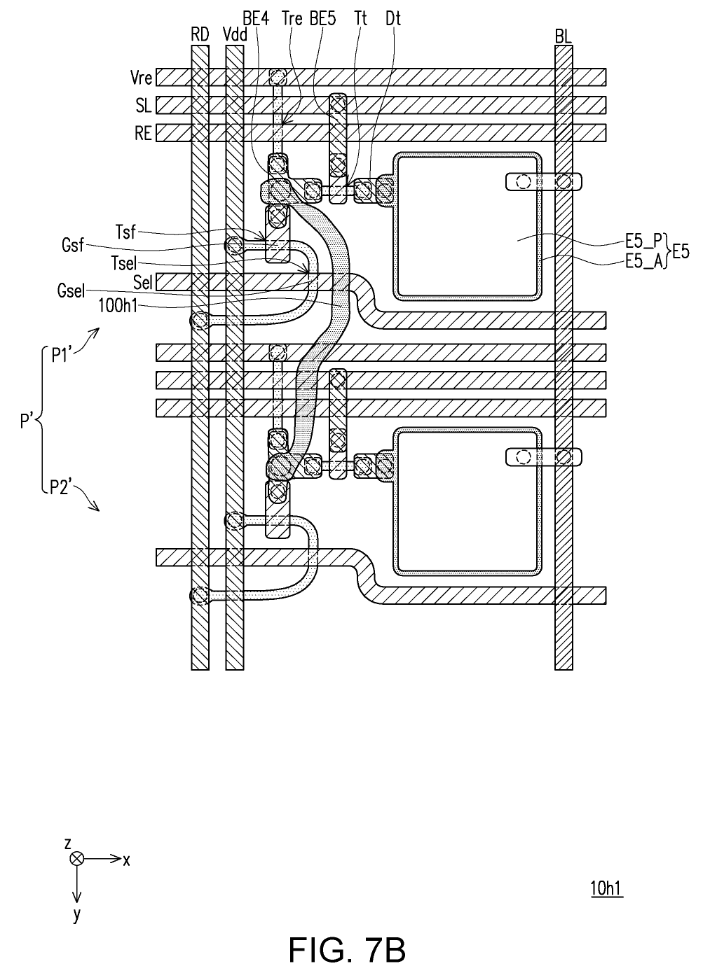

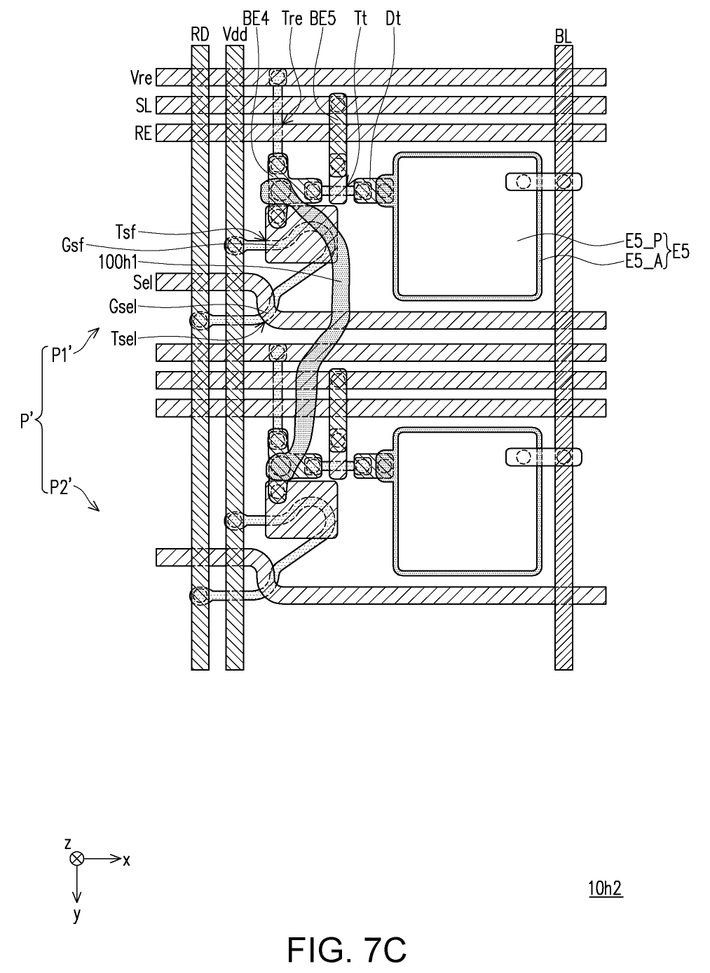

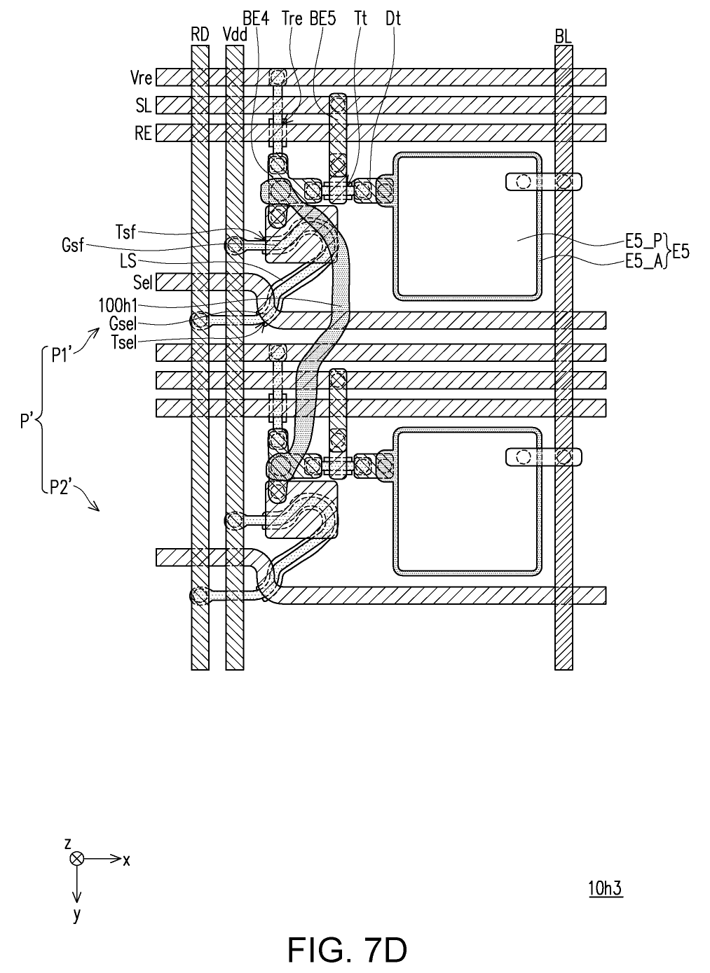

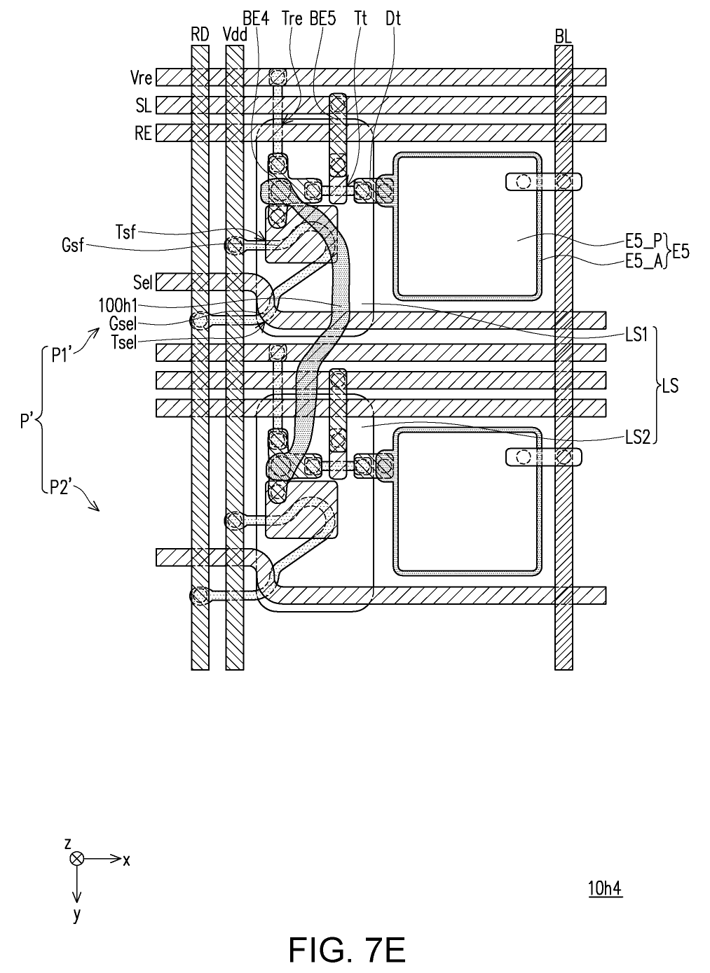

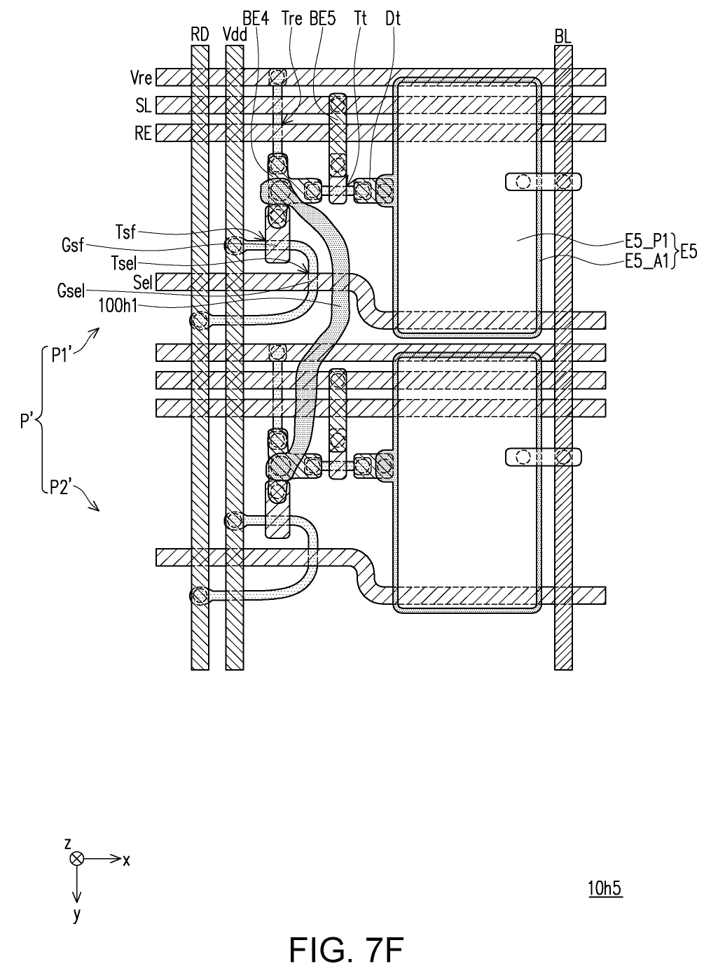

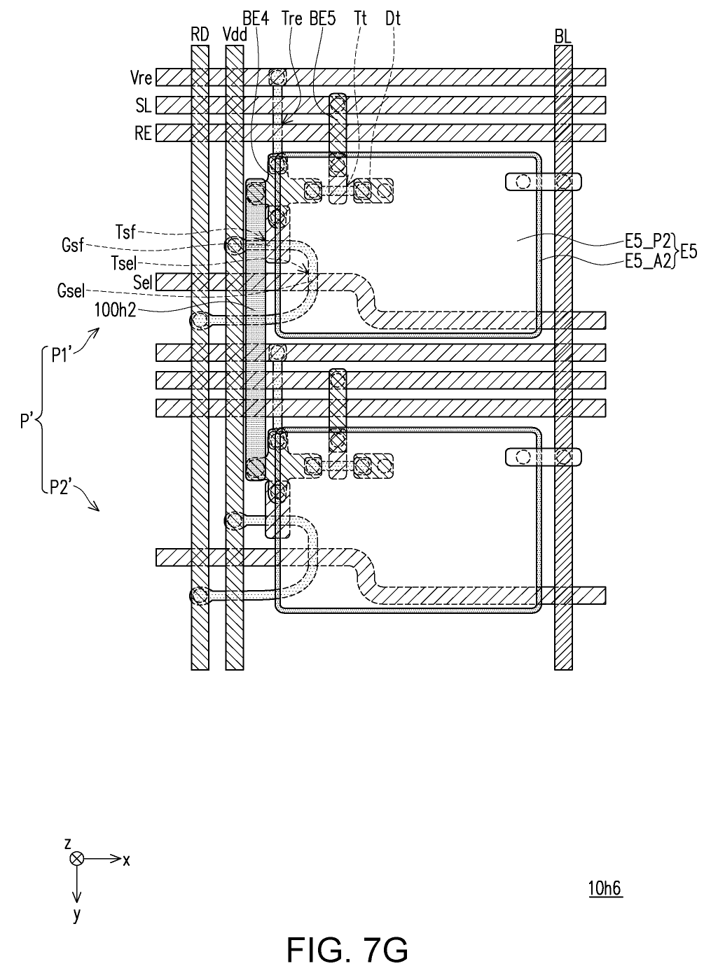

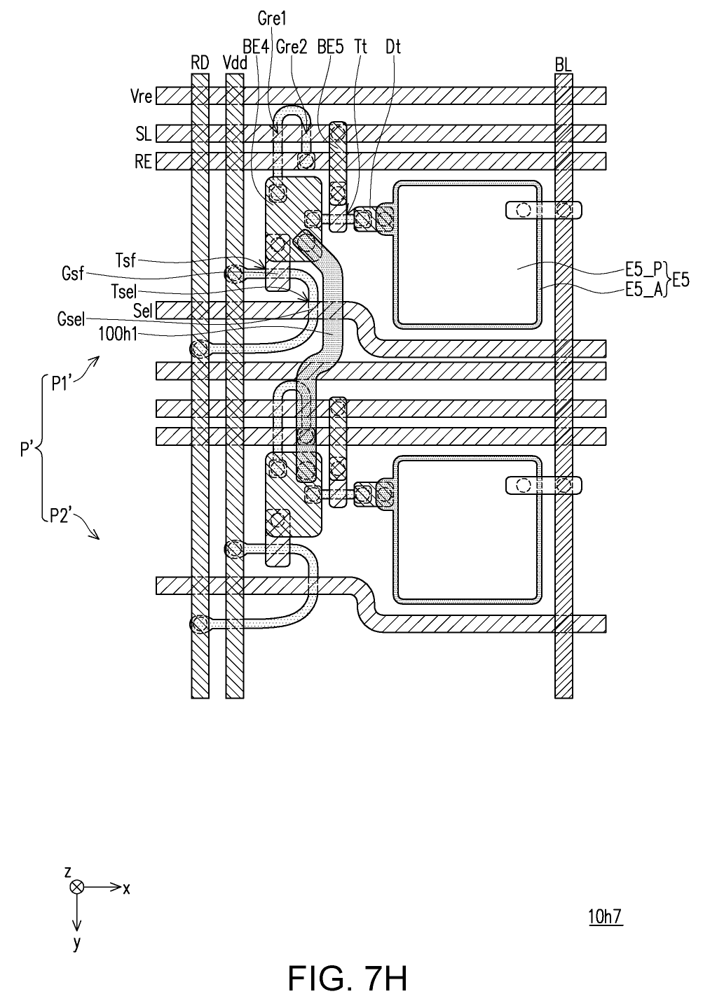

Referring to FIG. 7A, the main difference between an electronic device 10h and the electronic device 10f is that the selection transistor Tsel, the drive transistor Tsf, the reset transistor Tre, and the transfer transistor Tt are low-temperature polycrystalline silicon thin-film transistors.

Referring to FIG. 7B, the sub-pixel unit P1' is, electrically connected to the sub-pixel unit P2' through a connecting element 100h1. In this embodiment, the connecting element 100h1 does not overlap with the gate Gsel of the selection transistor Tsel and the gate Gsf of the drive transistor Tsf in the top view direction z of the electronic device 10h1. The connecting element 100h1, the drive transistor Tsf, the reset transistor Tre, and the transfer transistor Tt are electrically connected to one another through the bridge electrode BE4.

Referring to FIG. 7C the semiconductor SEsf of the drive transistor Tsf in the electronic device 10h2 may have a longer length than that in the electronic device 10h1.

Referring to FIG. 7D, in this embodiment, an electronic device 10h3 also includes a light-shielding layer LS which is disposed corresponding to the respective semiconductors of the respective transistors. In some embodiments, in the case where the light-shielding layer LS includes a conductive material, the light-shielding layer LS may also serve as the bottom gate of the transistor to improve the performance of the transistor.

Referring to FIG. 7E, the light-shielding layer LS includes multiple conductive patterns, wherein one of the multiple conductive patterns (light-shielding layer LS1) at least overlaps with the semiconductors of the respective transistors in the sub-pixel unit P1', and another of the multiple conductive patterns (light-shielding layer LS2) at least overlaps with the semiconductors of the respective transistors in the sub-pixel unit P2'.

Referring to FIG. 7F, a photosensitive layer E5_P1 and a first electrode E5_A1 in an electronic unit E5 of an electronic device 10h5 may extend in the direction y, and may partially overlap with at least one of the reset voltage line Vre, the scan line SL, the reset line RE, and the selection line SE, but the disclosure is not limited thereto. Based on this, the photosensitive layer E5_P1 in the electronic unit E5 may have a relatively large fill factor, to improve the sensing effect.

Referring to FIG. 7G, a photosensitive layer E5_P2 and a first electrode E5_A2 in an electronic unit E5 of an electronic device 10h6 extend in the direction y, and may partially overlap with the selection line SE. In addition, the photosensitive layer E5_P2 in the electronic unit E5 may also extend in the direction x, and may partially overlap with at least one of the selection transistor Tsel, the drive transistor Tsf, the reset transistor Tre, and the transfer transistor Tt.

Referring to FIG. 7H, the reset transistor Tre in the electronic unit E5 is a dual-gate transistor. That is, the reset transistor Tre includes a gate Gre1 and a gate Gre2.

Referring to FIG. 7I, the main difference between an electronic device 10i and the electronic device 10h is that a connecting element 100i further extends to at least partially overlap with the drive transistor Tsf, the reset transistor Tre, and the transfer transistor Tt. In this embodiment, the drive transistor Tsf, the reset transistor Tre, and the transfer transistor Tt may be electrically connected to one another through the bridge electrode BE4.

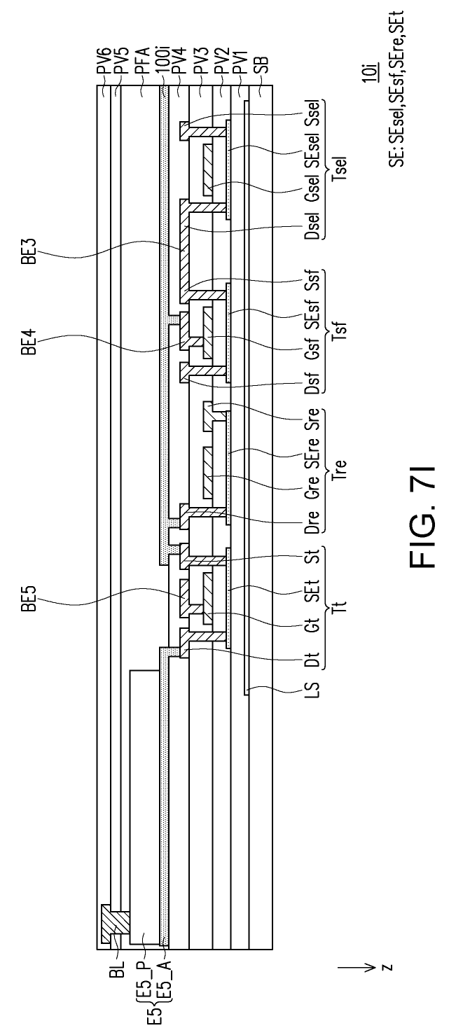

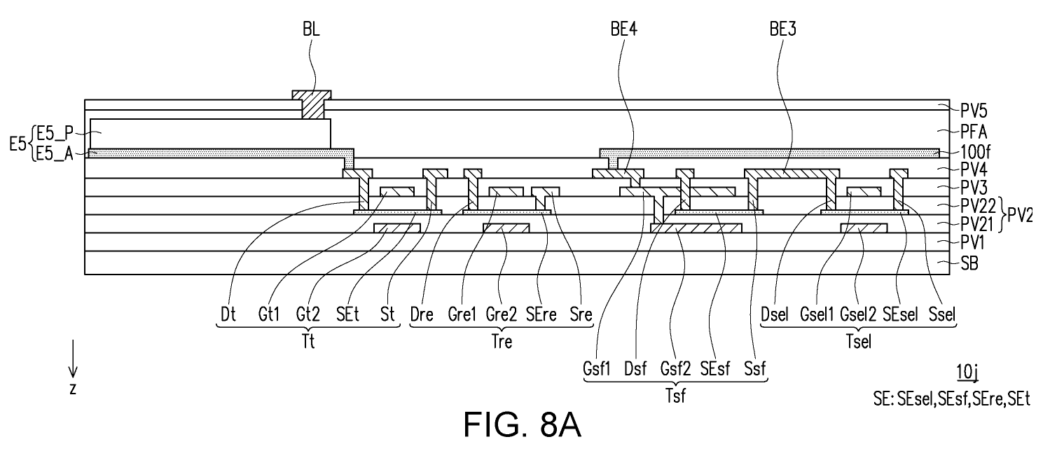

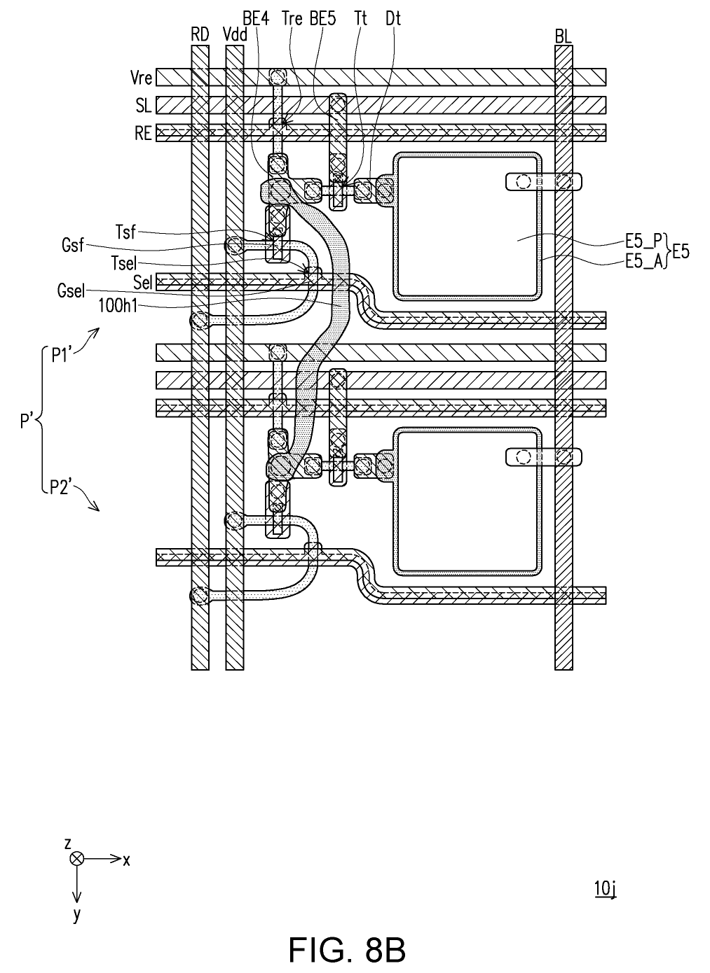

Referring to FIG. 8A and FIG. 8B, the main difference between an electronic device 10j and the electronic device 10h is that the respective transistors are oxide thin-film transistors(TFT). The material of the semiconductor in respective transistors include metal oxide. The selection transistor Tsel includes a top gate Gsel1 and a bottom gate Gsel2, the drive transistor Tsf includes a top gate Gsf1 and a bottom gate Gsf2, the reset transistor Tre includes a top gate Gre1 and a bottom gate Gre2, and the transfer transistor Tt includes a top gate Gt1 and a bottom gate Gt2. The insulation layer PV2 includes an insulation sublayer PV21 disposed between the bottom gate and the semiconductor and an insulation sublayer PV22 disposed between the top gate and the semiconductor.

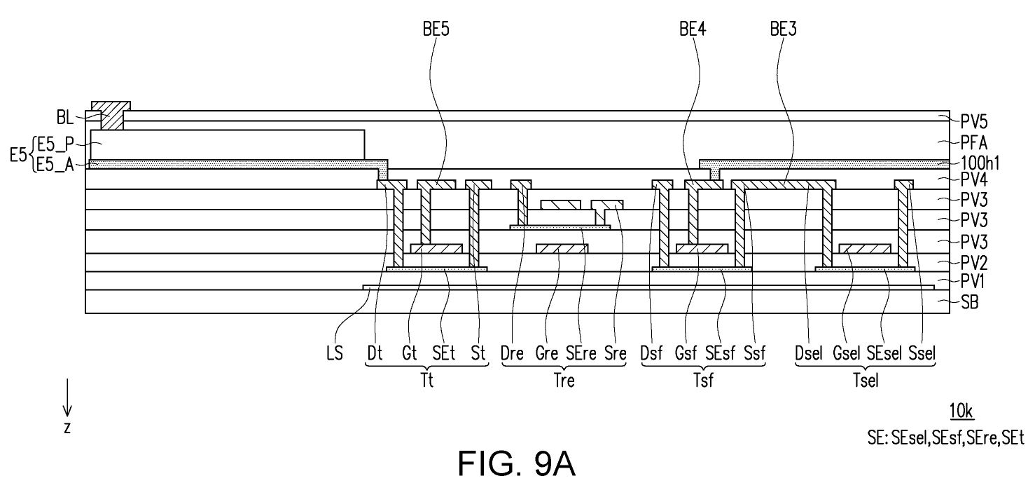

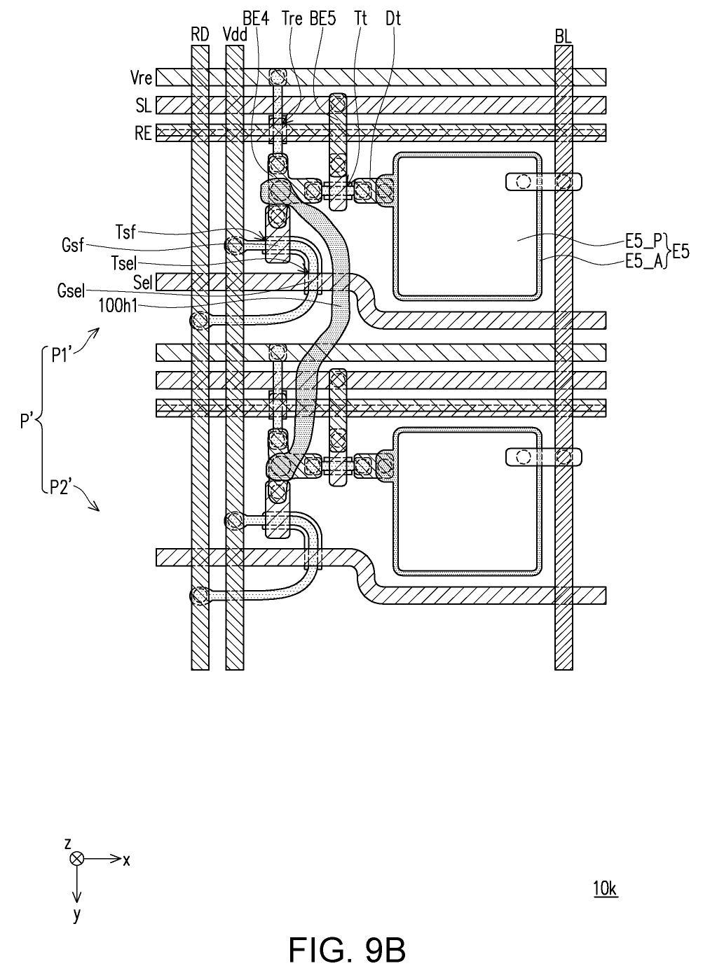

Referring to FIG. 9A and FIG. 9B, the main difference between an electronic device 10k and the electronic device 10h is that the reset transistor Tre in the electronic device 10k is an oxide TFT. Based on this, other transistors in the electronic device 10k may include low-temperature polycrystalline silicon (LTPS) thin-film transistors. The electronic device 10k also includes a light-shielding layer LS disposed corresponding to the respective semiconductors of the respective transistors, and disposed between the substrate SB and the semiconductors.

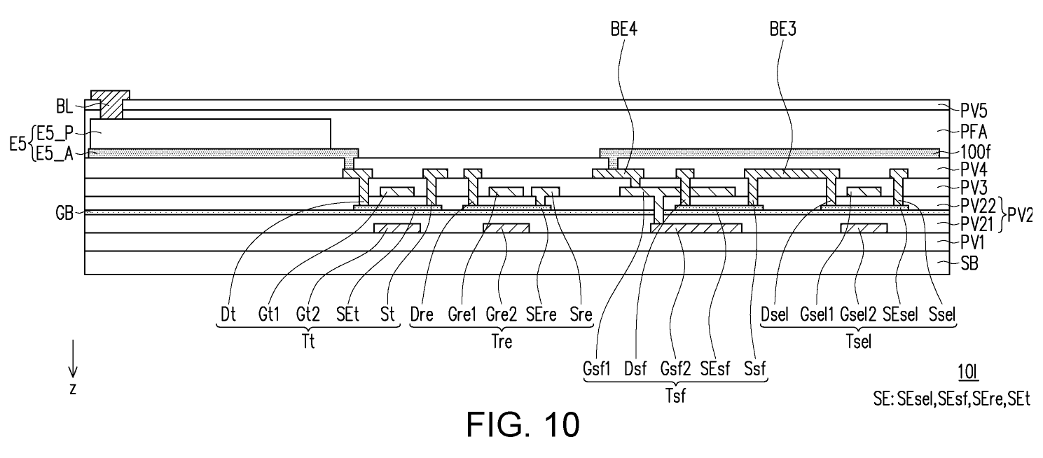

Referring to FIG. 10, the main difference between an electronic device 10l and the electronic device 10i is that the electronic device 10l also includes a blocking layer GB. The blocking layer GB contacts the respective semiconductors of the respective transistors, to reduce the possibility of hydrogen atoms and/or oxygen atoms entering the semiconductors, thereby improving the performance of the electronic device 10l. The blocking layer GB is disposed between the respective semiconductors of the respective transistors and the insulation layer PV2, and overlaps with the semiconductors.

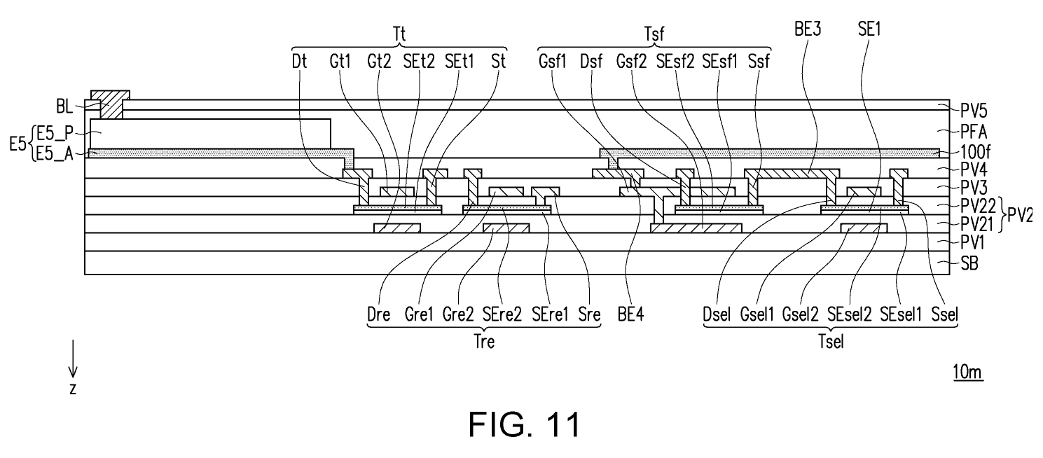

Referring to FIG. 11, the main difference between an electronic device 10m and the electronic device 10i is that the respective semiconductors of the selection transistor Tsel, the drive transistor Tsf, the reset transistor Tre, and the transfer transistor Tt have multi-layer structures. The semiconductor of each of the respective transistors is a stacked structure having two layers in contact with each other, including semiconductor SEsel1, semiconductor SEsel2, semiconductor SEsf1, semiconductor SEsf2, semiconductor SEre1, semiconductor SEre2, semiconductor SEt1, and semiconductor SEt2. The lower-layer semiconductor SEsel1, semiconductor SEsf1, semiconductor SEre1, and semiconductor SEt1 in the two-layer stacked structure may include high mobility oxide (HMO) semiconductors.

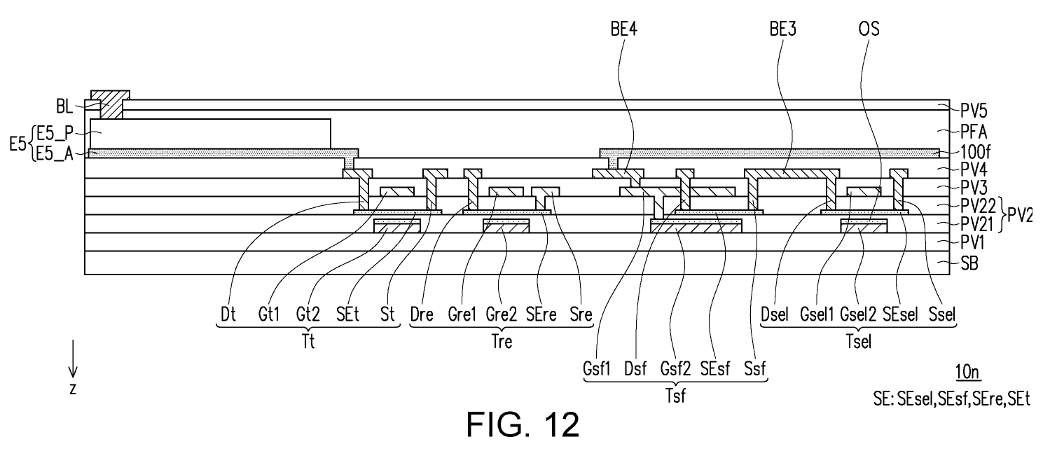

Referring to FIG. 12, the main difference between an electronic device 10n and the electronic device 10i is the electronic device 10n includes an oxygen supplementation layer OS. The oxygen supplementation layer OS contacts the respective bottom gates of the respective transistors, and disposed between the bottom gates and the semiconductors, to improve the carrier mobility of the transistors and enhance the performance of the electronic device 10n. In this embodiment, the oxygen supplementation layer OS is disposed corresponding to the respective bottom gates of the respective transistors. The electronic device 10n also includes another oxygen supplementation layer. This oxygen supplementation layer contacts and corresponds to the respective top gates of the respective transistors, and be disposed between the top gates and the semiconductors, to further enhance the performance of the electronic device 10n.

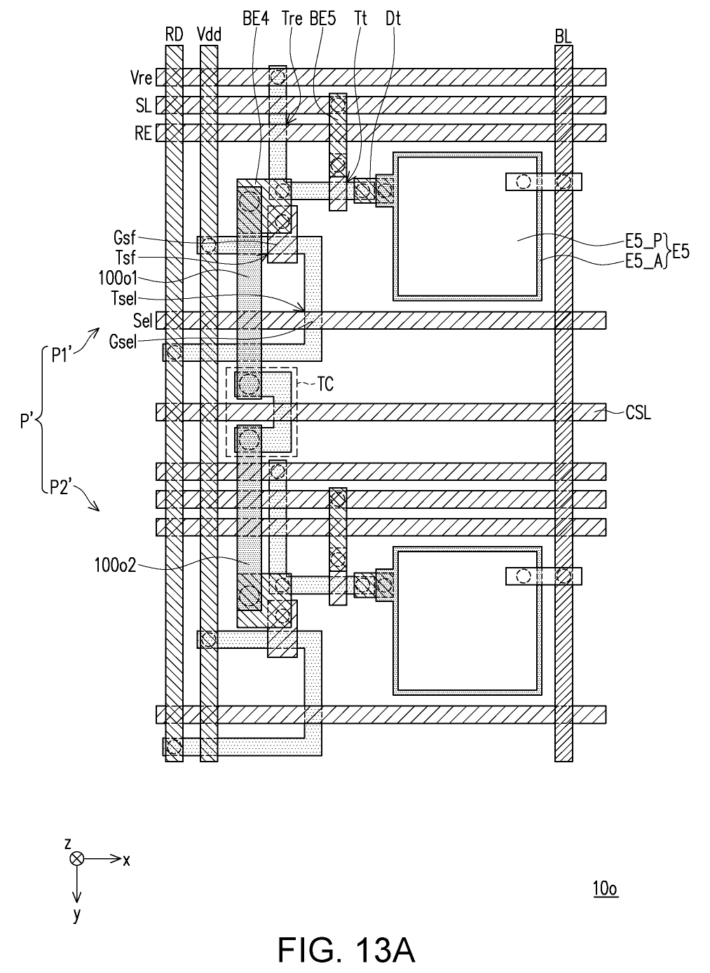

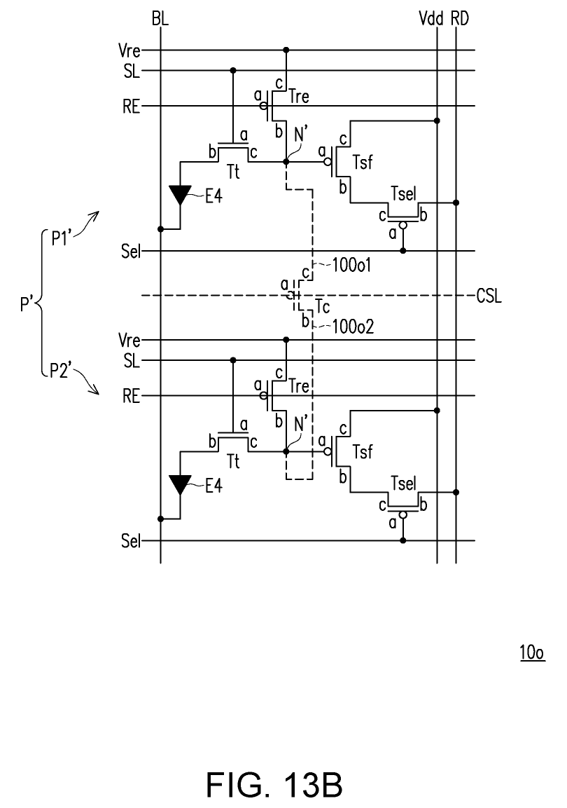

Referring to FIG. 13A and FIG. 13B, the main difference between an electronic device 10o and the aforementioned electronic device 10n is that the electronic device 10o also includes a control transistor Tc and a control scan line CSL. Therefore, the control scan line CSL may be used to provide a signal to the control transistor Tc, so as to determine whether to establish electrical connection between the sub-pixel units P1' and P2'.

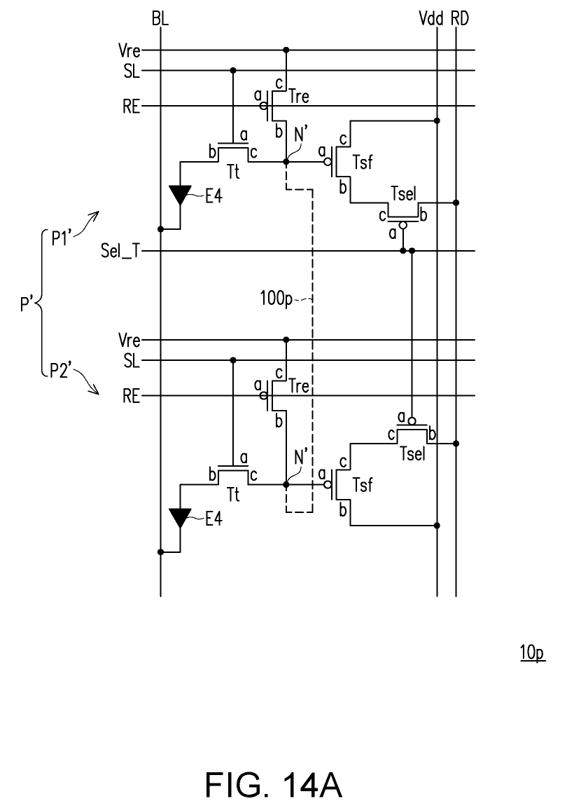

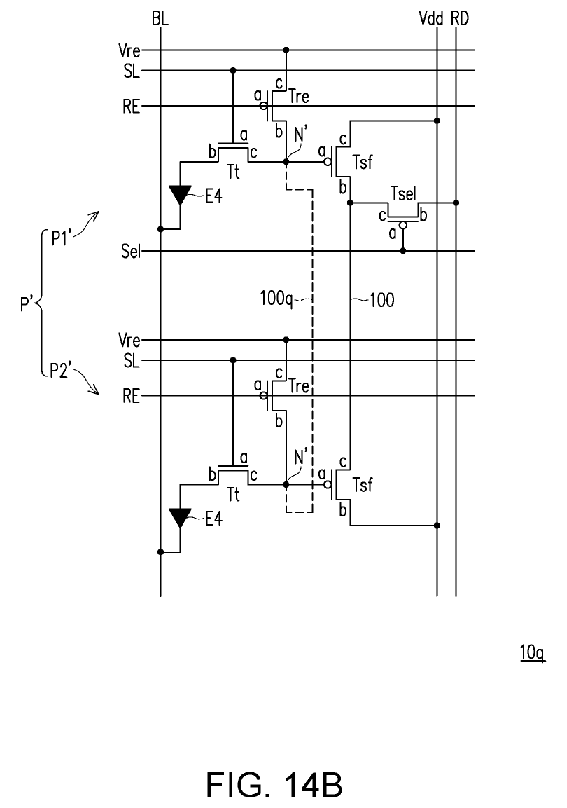

Referring to FIG. 14A, the main difference between an electronic device 10p and the electronic device 10e is that the sub-pixel units P1' and P2' share one selection line Sel_T. The selection line Sel_T respectively electrically connected to the control terminal a of the selection transistor Tsel in the sub-pixels unit P1' and P2'.

Referring to FIG. 14B, the main difference between an electronic device 10q and the electronic device 10p is that the sub-pixel unit P2' does not include the selection transistor Tsel. The selection transistor Tsel in the sub-pixel unit P1' is used to provide the current output by the drive transistor Tsf in the sub-pixel unit P2' to the read line RD.

To sum up, in some embodiments of the electronic device, adjacent sub-pixel units are electrically connected to each other through the connecting element. Accordingly, during the stage when the electronic unit in one sub-pixel unit is driven, the electronic unit in the adjacent sub-pixel unit is driven again in this stage, to enhance the characteristics exhibited by the electronic device. Overall, the electronic device according to some embodiments of the disclosure have both the characteristics of high resolution and high refresh rate.

What is claimed is:

1. An electronic device, comprising:
a substrate;
a first signal line disposed on the substrate;
a first electronic unit and a second electronic unit disposed on the substrate and respectively electrically connected to the first signal line;
a first transistor disposed on the substrate and comprising a first control element, a first conductive element, and a first semiconductor, wherein the first conductive element is electrically connected to the first semiconductor, and the first control element is electrically connected to the first electronic unit;
a second transistor disposed on the substrate and comprising a second control element, a second conductive element, and a second semiconductor, wherein the second conductive element is electrically connected to the second semiconductor, and the second control element is electrically connected to the second electronic unit; and
a first connecting element electrically connected to the first control element of the first transistor and the second control element of the second transistor,
wherein the first semiconductor overlaps with the first control element and is disposed between the substrate and the first control element, and
wherein the second semiconductor overlaps with the second control element and is disposed between the substrate and the second control element.

2. The electronic device according to claim 1, wherein the first control element is disposed between the first connecting element and the first semiconductor.

3. The electronic device according to claim 2, wherein the first conductive element is directly connected to the first semiconductor, and the first connecting element and the first conductive element of the first transistor are made of a same layer.

4. The electronic device according to claim 2, wherein the first electronic unit comprises a third conductive element, a fourth conductive element, and a third semiconductor, wherein the third semiconductor is disposed between the third conductive element and the fourth conductive element.

5. The electronic device according to claim 4, wherein the first connecting element and the third conductive element of the first electronic unit are made of a same layer.

6. The electronic device according to claim 5, wherein the first connecting element and the first control element of the first transistor are electrically connected through a second connecting element.

7. The electronic device according to claim 6, wherein the first conductive element is directly connected to the first semiconductor, and the second connecting element and the first conductive element of the first transistor are made of a same layer.

8. The electronic device according to claim 1, further comprising:
a third transistor comprising a fifth conductive element and a fourth semiconductor; and
a fourth transistor comprising a sixth conductive element, a seventh conductive element, and a fifth semiconductor,
wherein the fifth conductive element is electrically connected to the fourth semiconductor, the sixth conductive element and the seventh conductive element are respectively electrically connected to the fifth semiconductor, the first connecting element is electrically connected to the fifth conductive element of the third transistor and the sixth conductive element of the fourth transistor, and the seventh conductive element of the fourth transistor is electrically connected to the first electronic unit.

9. The electronic device according to claim 8, wherein the first semiconductor and the fourth semiconductor are the same in material.

10. The electronic device according to claim 8, wherein the first semiconductor and the fourth semiconductor are different in material.

11. The electronic device according to claim 10, wherein the fourth semiconductor is an oxide semiconductor, and the first semiconductor is a polycrystalline silicon semiconductor.

12. The electronic device according to claim 8, wherein the first electronic unit is configured to sense light.

13. The electronic device according to claim 12, further comprising a scintillator, wherein the scintillator is disposed on the first electronic unit to generate the light, and the first connecting element overlaps with the scintillator.

14. The electronic device according to claim 1, further comprising a metal oxide element, wherein the metal oxide element overlaps with the first semiconductor, and the first semiconductor is an oxide semiconductor.

15. The electronic device according to claim 14, wherein the metal oxide element is in direct contact with the first semiconductor.

16. The electronic device according to claim 14, wherein the metal oxide element is in direct contact with the first control element.

17. The electronic device according to claim 14, further comprising a third control element, wherein the third control element overlaps with the first semiconductor, and the first semiconductor is disposed between the first control element and the third control element.

18. The electronic device according to claim 17, wherein the metal oxide element is in direct contact with the third control element.
